(19) United States
(12) Patent Application Publication
(10) Pub. No.: US 2012/0287393 A1
(43) Pub. Date: Nov. 15, 2012

(54) POSITIVE PHOTOSENSITIVE RESIN COMPOSITION AND METHOD FOR FORMING PATTERNS BY USING THE SAME

(75) Inventors: Chi-Ming LIU, KAOHSIUNG CITY (TW); Chun-An SHIH, TAINAN CITY (TW)

(73) Assignee: CHI MEI COOPERATION, Tainan City (TW)

(21) Appl. No.: 13/457,469

(22) Filed: Apr. 26, 2012

(30) Foreign Application Priority Data
May 11, 2011 (TW) 100116529

(51) Int. Cl. G02F 1/1333; G03F 7/008; G03F 7/20; H01L 29/786

(52) U.S. Cl. 349/158; 257/57; 430/281.1; 430/326; 257/E29.273

(57) ABSTRACT

A positive photosensitive resin composition and a method for forming patterns by using the same are disclosed. The photosensitive resin composition comprises a novolac resin (A), an ortho-naphthoquinone diazide sulfonic acid ester (B), a dye (C) and a solvent (D). The novolac resin (A) includes a high-ortho novolac resin (A-1) that has ortho-ortho methylene bonding to all methylene bonding in a ratio of 18% to 25%, thereby exhibiting excellent temporal stability and forming patterns with high resolution.

### RELATED APPLICATIONS

This application claims priority to Taiwan Application Serial Number 100116529, filed on May 11, 2011, which is herein incorporated by reference.

### BACKGROUND

1. Field of Invention

The present invention relates to a positive photosensitive resin composition and a method for forming patterns by using the same. More particularly, the present invention relates to a positive photosensitive resin composition exhibiting excellent temporal stability and having high resolution and a method for forming patterns by using the same during the fabricating process of components such as semiconductor integrated circuit (IC), thin-film transistor (TFT) and the like of a liquid crystal display (LCD) device or a touch panel.

2. Description of Related Art

Recently, the semiconductor industry and liquid crystal display (LCD) device industry make the remarkable progress, the demand for personal computers and LCD continuously increases and the related technologies have a drastic advance, resulting in the higher resolution requirement. For satisfying those demands, a high-ortho novolac resin and a photosensitizer are typically added into the positive photosensitive resin composition, such as Japanese Patent Laid-Open No. 2009-192571.

During the processes of the semiconductor integrated circuit device, the thin-film transistor of LCD or touch panel, the usage of the photosensitizer in the positive photosensitive resin composition is usually adjusted to reach higher exposure latitude; however, such photosensitive resin composition often causes the problem of temporal instability.

Accordingly, it is necessary to provide a positive photosensitive resin composition for improving shortcomings of lower resolution and temporal instability of the prior positive photosensitive resin composition.

### SUMMARY

A positive photosensitive resin composition having excellent temporal stability is provided, which comprises a novolac resin (A), an ortho-naphthoquinone diazide sulfonic acid ester (B), a dye (C) and a solvent (D).

Moreover, a method for forming patterns is provided, which is formed by subjecting the aforementioned positive photosensitive resin composition into a prebake step, an exposure step, a developing step and a postbake step, thereby forming the patterns on a substrate.

Furthermore, a thin-film transistor array substrate is provided, which comprises a pattern formed by using the aforementioned method.

In addition, a liquid crystal display device, which comprises the aforementioned thin-film transistor array substrate, thereby improving the problems of worse temporal stability and low resolution in the prior positive photosensitive resin composition.

Accordingly, the invention provides a positive photosensitive resin composition. The positive photosensitive resin composition comprises a novolac resin (A), an ortho-naphthoquinone diazide sulfonic acid ester (B), a dye (C) and a solvent (D) all of which are described in detail as follows.

### Novolac Resin (A)

The novolac resin (A) comprises a high-ortho novolac resin (A-1) and optionally includes other novolac resin (A-2).

The aforementioned high-ortho novolac resin (A-1) is typically obtained by condensing an aromatic hydroxyl compound with an aldehyde in the presence of a two-valent metal salt catalyst under an acidic environment (for example, pH 1 to 5), followed by dehydration under the reduced pressure. Alternatively, an acid catalyst can be further added in the dehydration condensation reaction, and unreactive monomers are removed. The details of the dehydration condensation reaction can be referred to Japanese Patent Publication No. 55-090523, Japanese Patent Publication No. 59-080418 and Japanese Patent Publication No. 62-230815 without reciting it in detail.

Examples of the aromatic hydroxyl compound include but are not limited cresols such as phenol, m-cresol, p-cresol, o-cresol and the like; xylenols such as 2,3-dimethylphenol, 3,5-dimethylphenol, 2,5-dimethylphenol, 3,4-dimethylphenol and the like; alkyl phenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-cresol, 2-tert-butyl-5-cresol, 6-tert-butyl-3-cresol and the like; alkoxy phenols such as p-methoxyphenol, m-methoxyphenol, p-ethoxyphenol, m-ethoxyphenol, p-propoxyphenol, m-propoxyphenol and the like; isopropenyl phenols such as o-isopropenyl phenol, p-isopropenyl phenol, 2-methyl-4-isopropenyl phenol, 2-ethyl-4-isopropenyl phenol and the like; aryl phenols such as phenyl phenol; and polyhydroxyphenols such as 4,4′-dihydroxybiphenyl, bisphenol A, resorcinol, hydroquinone, pyrogallol and the like. The aforementioned aromatic hydroxyl compounds may be used alone or in combinations of two or more. Among those compounds, o-cresol, m-cresol, p-cresol, 2,5-dimethylphenol, 3,5-dimethylphenol and 2,3,5-triethylphenol are preferred.

Examples of the aforementioned aldehyde that is suitable to condense with the aromatic hydroxyl compound include but are not limited to formaldehyde, paraformaldehyde, trioxane, acetaldehyde, propanal, butanal, trimethyl acetaldehyde, acrolein, crotonaldehyde, cyclohexanealdehyde, furfural, furylacrolein, benzaldehyde, terephthal aldehyde, phenylacetaldehyde, α-phenylpropanal, β-phenylpropanal, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, cinnamaldehyde and the like. The aforementioned aldehydes may be used alone or in combinations of two or more. Among those aldehydes, formaldehyde is preferred.

During the preparation of the high-ortho novolac resin (A-1), the aromatic hydroxyl compound and the aldehyde are typically used in a molar ratio of 1:0.5 to 1:0.85, preferably 1:0.55 to 1:0.82 and more preferably 1:0.6 to 1:0.8.

Examples of the aforementioned two-valent metal salt catalyst include but are not limited to zinc acetate, manganese acetate, barium acetate, manganese nitrate, zinc borate, zinc chloride, zinc oxide and the like. The aforementioned two-valent metal salt catalysts may be used alone or in combinations of two or more. Based on 100 parts by weight of the aromatic hydroxyl compound, an amount of the two-valent metal salt catalyst is typically 0.01 to 1.0 parts by weight, preferably 0.03 to 0.8 parts by weight and more preferably 0.05 to 0.5 parts by weight.

Examples of the aforementioned acid catalyst include but are not limited to dimethyl sulfate, diethyl sulfate, dipropyl sulfate and the like. The aforementioned acid catalysts may be used alone or in combinations of two or more. Based on 100 parts by weight of the aromatic hydroxyl compound, an amount of the acid catalyst is typically 0.005 to 1.0 parts by weight, preferably 0.008 to 0.8 parts by weight and more preferably 0.01 to 0.5 parts by weight.

The high-ortho novolac resin (A-1) of the present invention typically has ortho-ortho methylene bonding to all methylene bonding in a ratio of 18% to 25%, preferably in a ratio of 19% to 25% and more preferably in a ratio of 20% to 25%. It is worthy mentioning that the patterns formed by a positive photosensitive resin composition would have the problems of low resolution if such positive photosensitive resin did not include the high-ortho novolac resin (A-1).

The aforementioned other novolac resin (A-2) is typically obtained by condensing the aforementioned aromatic hydroxyl compound with the aldehyde in the presence of a prior organic acid catalyst and/or inorganic acid catalyst such as hydrochloric acid, sulfuric acid, formic acid, acetic acid, oxalic acid, p-toluenesulfonic acid and the like, followed by dehydration under normal pressure and removal of unreactive monomers. The aforementioned other novolac resin (A-2) has ortho-para, para-para or ortho-ortho methylene bonding randomly.

Based on 100 parts by weight of the novolac resin (A), an amount of the high-ortho novolac resin (A-1) is typically 30 to 100 parts by weight, preferably 40 to 100 parts by weight and more preferably 50 to 100 parts by weight. When the positive photosensitive resin composition includes 30 to 100 parts by weight of the high-ortho novolac resin (A-1), the pattern with high residual film ratio can be formed on a substrate.

### Ortho-Naphthoquinone Diazide Sulfonic Acid Ester (B)

The ortho-naphthoquinone diazide sulfonic acid ester (B) can use the ones that are used widely in the prior art but have no specific limitation. Preferably, the ortho-naphthoquinone diazide sulfonic acid ester (B) can be an ester of an ortho-naphthoquinone diazide sulfonic acid and a hydroxy compound, in which the ortho-naphthoquinone diazide sulfonic acid is exemplified as ortho-naphthoquinone diazide-4-sulfonic acid, ortho-naphthoquinone diazide-5-sulfonic acid and ortho-naphthoquinone diazide-6-sulfonic acid. More preferably, the ortho-naphthoquinone diazide sulfonic acid ester (B) can be an ester of the ortho-naphthoquinone diazide sulfonic acid and a polyhydroxy compound. The aforementioned esters can be completely or partially esterified. Examples of the hydroxy compound can be (1) hydroxybenzophenones; (2) hydroxyaromatic compounds of formula (I); (3) (hydroxyphenyl)hydrocarbons of formula (II); (4) other aromatic hydroxy compounds and the like.

(1) Hydroxybenzophenones are exemplified as 2,3,4-trihydroxybenzophenone, 2,4,4′-trihydroxybenzophenone, 2,4,6-trihydroxybenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5′-pentahydroxybenzophenone, 2,3′,4,5,5′-pentahydroxybenzophenone, 2,3,3′,4,4′,5′-hexahydroxybenzophenone and the like.

(2) Hydroxyaromatic compounds are exemplified as the following formula (I):

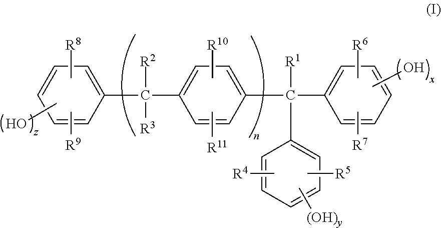

In formula (I), R¹, R² and R³ represent hydrogen atom or a lower alkyl group. R⁴, R⁵, R⁶, R⁷, R⁸ and R⁹ represent hydrogen atom, halogen atom, a lower alkyl group, a lower alkoxy group, a lower alkenyl group and a cycloalkyl group. R¹⁹ and R¹¹ represent oxygen atom, halogen atom, a lower alkyl group. x, y and z independently represent an integer of 1 to 3, and n independently represent an integer of 0 to 1.

Specific examples of the hydroxyaromatic compound of the formula (I) include but are not limited to tris(4-hydroxyphenyl) methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-dimethylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-3,5-dimethylphenyl)-2,4-dihydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methylaryl)-2-hydroxyphenyl methane, bis(3-cyclohexyl-4-hydroxy-6-methylphenyl)-3-hydroxyphenyl methane, bis(3-cyclohexyl-4-hydroxy-6-methylphenyl)-4-hydroxyphenyl methane, bis(3-cyclohexyl-4-hydroxy-6-methylphenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methylphenyl)-3,4-dihydroxyphenyl methane, 1-[1-(4-hydroxylphenyl)isopropyl]-4-[1,1-bis(4-hydroxyphenyl)ethyl] benzene, 1-[1-(3-methyl-4-hydroxylphenyl)isopropyl]-4-[1,1-bis(3-methyl-4-hydroxylphenyl) ethyl] benzene.

(3) (Hydroxyphenyl)hydrocarbons are exemplified as the following formula (II):

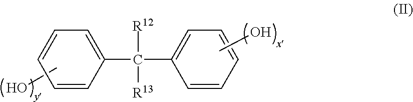

In formula (II), R¹² and R¹³ represent hydrogen atom or a lower alkyl group. x′ and y′ independently represent an integer of 1 to 3.

Specific examples of the (hydroxyphenyl)hydrocarbon of the formula (II) include but are not limited to 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, bis(2,3,4-trihydroxyphenyl) methane, bis(2,4-dihydroxyphenyl) methane and the like.

(4) Other aromatic hydroxy compounds are exemplified as phenol, p-methoxy phenol, dimethyl phenol, hydroquinone, bisphenol A, naphthol, pyrocatechol, 1,2,3-pyrogallol monomethyl ether, 1,2,3-pyrogallol-1,3-dimethyl ether, 3,4,5-trihydroxybenzoic acid (gallic acid), partially esterified or partially etherified gallic acid and the like.

Among those hydroxy compounds, 2,3,4-trihydroxybenzophenone and 2,3,4,4′-tetrahydroxybenzophenone are preferable. The aforementioned hydroxy compounds may be used alone or in combinations of two or more.

The ortho-naphthoquinone diazide sulfonic acid ester (B) of the present positive photosensitive resin composition can use a quinone diazide compound such as ortho-naphthoquinone diazide-4-(or -5-) sulfonyl halide salt, followed by condensation with (1) to (4) of the hydroxy compounds to achieve complete or partial esterification. The aforementioned condensation is usually carried out in an organic solvent such as dioxane, N-pyrrolidone, acetamide or the like. Simultaneously, the condensation is more advantageously carried out in the presence of an alkaline condensing agent such as triethanolamine, alkali metal carbonate or alkali metal bicarbonate or the like.

Based on 100 mole percents of the total hydroxy group of the hydroxy compound, esterification of the ortho-naphthoquinone diazide-4-(or -5-) sulfonyl halide salt is preferably condensed with 50 mole percents of hydroxy group the hydroxy compound, and more preferably condensed with 60 mole percents of hydroxy group the hydroxy compound. In other word, the esterification degree is equal to or more than 50 percents, and more preferably more than 60 percents.

Based on 100 parts by weight of the novolac resin (A), an amount of the ortho-naphthoquinone diazide sulfonic acid ester (B) is typically 1 to 100 parts by weight, preferably 5 to 80 parts by weight and more preferably 10 to 60 parts by weight.

### Dye (C)

There is no specific limitation to the dye used in the present invention. The aforementioned dye can be at least one dye selected from the group consisting of an acid dye, a basic dye, a direct dye, a sulphur dye, a vat dye, a naphthol dye, a reactive dye, a disperse dye and an oil-soluble dye.

Specific examples of the acid dye include but are not limited to color index number (C.I. No.) Acid Red 1, 6, 8, 9, 11, 13, 18, 26, 27, 35, 37, 52, 54, 57, 60, 73, 82, 88, 97, 106, 111, 114, 118, 119, 127, 131, 138, 143, 145, 151, 183, 186, 195, 198, 211, 215, 217, 225, 226, 249, 251, 254, 256, 257, 260, 261, 265, 266, 274, 276, 277, 289, 296, 299, 315, 318, 336, 337, 357, 359, 361, 362, 364, 366, 399, 407, 415; C.I. Acid Green 9, 12, 16, 19, 20, 25, 27, 28, 40, 43, 56, 73, 81, 84, 104, 108, 109; C.I. Acid Blue 1, 7, 9, 15, 22, 23, 25, 40, 62, 72, 74, 78, 80, 83, 90, 92, 103, 104, 112, 113, 114, 120, 127, 128, 129, 138, 140, 142, 156, 158, 167, 171, 182, 185, 193, 199, 201, 203, 204, 205, 207, 209, 220, 221, 224, 225, 229, 230, 239, 249, 258, 260, 264, 278, 279, 280, 284, 290, 296, 298, 300, 317, 324, 333, 335, 338, 342, 350; C.I. Acid Yellow 1, 3, 11, 17, 18, 19, 23, 25, 36, 38, 40, 42, 44, 49, 59, 61, 65, 67, 72, 73, 78, 79, 99, 104, 110, 114, 116, 118, 121, 127, 129, 135, 137, 141, 143, 151, 155, 158, 159, 169, 176, 184, 193, 200, 204, 207, 215, 219, 220, 230, 232, 235, 241, 242, 246 204, 207, 215, 219, 220, 230, 232, 235, 241, 242, 246; C.I. Acid Orange 3, 7, 8, 10, 19, 24, 51, 56, 67, 74, 80, 86, 87, 88, 89, 94, 95, 107, 108, 116, 122, 127, 140, 142, 144, 149, 152, 156, 162, 166, 168; C.I. Acid Violet 17, 19, 21, 42, 43, 47, 48, 49, 54, 66, 78, 90, 97, 102, 109, 126; C.I. Acid Brown 2, 4, 13, 14, 19, 28, 44, 123, 224, 226, 227, 248, 282, 283, 289, 294, 297, 298, 301, 355, 357, 413; C.I. Acid Black 1, 2, 3, 24, 26, 31, 50, 52, 58, 60, 63, 107, 109, 112, 119, 132, 140, 155, 172, 187, 188, 194, 207, 222 and so on.

Specific examples of the basic dye include but are not limited to C.I. Basic Red I, 2, 9, 12, 13, 14, 15, 17, 18, 22, 23, 24, 27, 29, 32, 34, 35, 36, 37, 38, 39, 40, 46, 51, 52, 69, 70, 73, 82, 109; C.I. Basic Green 1, 3, 4; C.I. Basic Blue 1, 3, 7, 9, 21, 22, 26, 41, 45, 47, 52, 54, 65, 66, 69, 75, 77, 92, 100, 105, 117, 124, 129, 147, 151; C.I. Basic Violet 1, 3, 7, 10, 14, 15, 16, 18, 21, 25, 26, 27, 28, 39; C.I. Basic Yellow 1, 2, 11, 13, 15, 19, 21, 23, 25, 28, 29, 32, 36, 40, 41, 45, 51, 63, 67, 70, 73, 91; C.I. Basic Orange 2, 5, 21, 22; C.I. Basic Brown 1 and so on.

Specific examples of the direct dye include but are not limited to C.I. Direct Red 2, 4, 9, 23, 24, 31, 54, 62, 69, 75, 76, 79, 80, 81, 83, 84, 89, 95, 149, 212, 224, 225, 226, 227, 239, 242, 243, 254; C.I. Direct Green 26, 28, 59, 80, 85; C.I. Direct Blue 1, 15, 71, 76, 77, 78, 80, 86, 87, 90, 98, 106, 108, 160, 168, 189, 192, 193, 199, 200, 201, 202, 203, 218, 225, 229, 237, 244, 248, 251, 270, 273, 274, 290, 291; C.I. Direct Violet 9, 35, 51, 66, 94, 95; C.I. Direct Yellow 8, 9, 10, 11, 12, 22, 26, 27, 28, 33, 39, 44, 50, 58, 86, 87, 98, 105, 106, 130, 132, 137, 142, 147, 153; C.I. Direct Orange 6, 26, 27, 29, 34, 37, 39, 40, 46, 72, 102, 105, 107, 118; C.I. Direct Brown 44, 106, 115, 195, 209, 210, 222, 223; C.I. Direct Black 17, 19, 22, 32, 51, 62, 108, 112, 113, 117, 118, 132, 146, 154, 159, 169 and so on.

Specific examples of the sulphur dye include but are not limited to C.I. Sulphur Red 5, 6, 7; C.I. Sulphur Green 2, 3, 6; C.I. Sulphur Blue 2, 3, 7, 9, 13, 15; C.I. Sulphur Violet 2, 3, 4; C.I. Sulphur Yellow 4 and so on.

Specific examples of the vat dye include but are not limited to C.I. Vat Red 13, 21, 23, 28, 29, 48; C.I. Vat Green 3, 5, 8; C.I. Vat Blue 6, 14, 26, 30; C.I. Vat Violet 1, 3, 9, 13, 15, 16; C.I. Vat Yellow 2, 12, 20, 33; C.I. Vat Orange 2, 5, 11, 15, 18, 20 and so on.

Specific examples of the naphthol dye include but are not limited to C.I. Azoic Coupling component 2, 3, 4, 5, 7, 8, 9, 10, 11, 13, 32, 37, 41, 48 and so on.

Specific examples of the reactive dye include but are not limited to C.I. Reactive Red 2, 3, 5, 8, 11, 21, 22, 23, 24, 28, 29, 31, 33, 35, 43, 45, 46, 49, 55, 56, 58, 65, 66, 78, 83, 84, 106, 111, 112, 113, 114, 116, 120, 123, 124, 128, 130, 136, 141, 147, 158, 159, 171, 174, 180, 183, 184, 187, 190, 193, 194, 195, 198, 218, 220, 222, 223, 228, 235; C.I. Reactive Blue 1, 2, 3, 4, 5, 7, 13, 14, 15, 19, 21, 25, 27, 28, 29, 38, 39, 41, 49, 50, 52, 63, 69, 71, 72, 77, 79, 89, 104, 109, 112, 113, 114, 116, 119, 120, 122, 137, 140, 143, 147, 160, 161, 162, 163, 168, 171, 176, 182, 184, 191, 194, 195, 198, 203, 204, 207, 209, 211, 214, 220, 221, 222, 231, 235, 236; C.I. Reactive Violet 1, 2, 4, 5, 6, 22, 23, 33, 36, 38; C.I. Reactive Yellow 1, 2, 3, 4, 7, 14, 15, 16, 17, 18, 22, 23, 24, 25, 27, 37, 39, 42, 57, 69, 76, 81, 84, 85, 86, 87, 92, 95, 102, 105, 111, 125, 135, 136, 137, 142, 143, 145, 151, 160, 161, 165, 167, 168, 175, 176; C.I. Reactive Orange 1, 4, 5, 7, 11, 12, 13, 15, 16, 20, 30, 35, 56, 64, 67, 69, 70, 72, 74, 82, 84, 86, 87, 91, 92, 93, 95, 107; C.I. Reactive Green 8, 12, 15, 19, 21; C.I. Reactive Brown 2, 7, 9, 10, 11, 17, 18, 19, 21, 23, 31, 37, 43, 46; C.I. Reactive Black 5, 8, 13, 14, 31, 34, 39 and so on.

Specific examples of the disperse dye include but are not limited to C.I. Disperse Red 4, 9, 11, 54, 55, 58, 60, 65, 72, 73, 86, 88, 91, 92, 93, 111, 126, 127, 129, 134, 135, 141, 143, 145, 152, 153, 154, 159, 164, 167:1, 177, 181, 196, 204, 206, 207, 210, 221, 229, 239, 240, 258, 277, 278, 283, 311, 323, 343, 348, 354, 356, 362; C.I. Disperse Blue 3, 24, 56, 60, 73, 79, 82, 87, 106, 113, 125, 128, 143, 148, 154, 158, 165, 165:1, 165:2, 176, 183, 185, 197, 198, 201, 214, 224, 225, 257, 266, 267, 287, 354, 358, 365, 368; C.I. Disperse Violet 1, 6, 12, 26, 27, 28, 33; C.I. Disperse Yellow 3, 4, 5, 7, 23, 33, 42, 54, 60, 64, 79, 82, 83, 93, 99, 100, 119, 122, 124, 126, 160, 184:1, 186, 198, 199, 204, 224, 237; C.I. Disperse Orange 13, 29, 30, 31:1, 33, 49, 54, 55, 66, 73, 118, 119, 163; C.I. Disperse Green 6:1, 9 and so on.

Specific examples of the oil-soluble dye include but are not limited to C.I. Solvent Yellow 14, 16, 19, 21, 25, 29, 33, 34, 56, 62, 81, 82, 83, 83:1, 88, 89, 146, 151, 162, 179; C.I. Solvent Red 1, 3, 8, 18, 23, 24, 25, 27, 30, 43, 48, 49, 51, 52, 58, 63, 72, 73, 81, 82, 83, 84, 90:1, 91, 92, 100, 109, 111, 121, 122, 125, 127, 130, 132, 135, 160, 179, 218, 233; C.I. Solvent Blue 2, 11, 44, 45, 67, 70, 97, 136; C.I. Solvent Green 1, 3, 4, 5, 7, 14, 20, 28, 29, 32, 33; C.I. Solvent Orange 1, 2, 3, 4, 5, 6, 7, 11, 12, 14, 20, 22, 23, 24, 25, 31, 41, 45, 47, 48, 54, 56, 58, 60, 62, 63, 75, 77, 80, 81, 86, 98, 99, 102, 103, 105, 106, 107, 109, 110, 111, 112, 113, 114, 115; C.I. Solvent Violet 3, 8, 13, 14, 21, 27; C.I. Solvent Black 3, 7, 27, 29, 34 and so on.

Based on 100 parts by weight of the novolac resin (A), an amount of the dye (C) is typically 0.1 to 5 parts by weight, preferably 0.3 to 4 parts by weight and more preferably 0.5 to 3 parts by weight.

It is worth mentioning that the photosensitive resin composition without the dye (C) would have the problem of worse temporal stability. In addition, the positive photosensitive resin composition will have excellent temporal stability and high resolution if such resin composition includes the high-ortho novolac resin (A-1) with ortho-ortho methylene bonding to all methylene bonding in a ratio of 18% to 25% and the dye (C).

### Solvent (D)

It is preferred to use a solvent (D) of the present invention that is dissolved but not reacted with other organic components.

Specific examples of the solvent (D) include but are not limited to (poly)alkylene glycol monoalkyl ethers such as ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monoethyl ether, tripropylene glycol monoethyl ether and the like; (poly)alkylene glycol monoalkyl ether acetates such as ethylene glycol monomethyl ether acetate, ethylene glycol monoethyl ether acetate, propylene glycol monomethyl ether acetate, propylene glycol monoethyl ether acetate and the like; other ethers such as diethylene glycol dimethyl ether, diethylene glycol methyl ethyl ether, diethylene glycol diethyl ether, tetrahydrofuran and the like; ketones such as methyl ethyl ketone, cyclohexanone, 2-heptanone, 3-heptanone and the like; alkyl lactates such as ethyl lactate, methyl 2-hydroxypropanoate, ethyl 2-hydroxypropanoate and the like; other esters such as methyl 2-hydroxy-2-methylpropanoate, ethyl 2-hydroxy-2-methylpropanoate, methyl 3-methoxypropanoate, ethyl 3-methoxypropanoate, methyl 3-ethoxypropanoate, ethyl 3-ethoxypropanoate, ethyl ethoxyacetate, ethyl hydroxyacetate, methyl 2-hydroxy-3-methylenebutyrate, 3-methyl-3-methoxybutyl acetate, 3-methyl-3-methoxybutyl propanoate, ethyl acetate, n-propyl acetate, isopropyl acetate, n-butyl acetate, isobutyl acetate, n-amyl acetate, isoamyl acetate, n-butyl propanoate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate and the like; aromatic hydrocarbons such as toluene, xylene and the like; carboxylic amines such as N-methylpyrrolidone, N,N-dimethylformamide, N,N-dimethylacetamide and the like. The solvent (D) may be used alone or in combinations of two or more. Among those solvents, propylene glycol monoethyl ether, propylene glycol monomethyl ether acetate and ethyl lactate are preferred.

Based on 100 parts by weight of the novolac resin (A), an amount of the solvent (D) is typically 500 to 2,000 parts by weight, preferably 600 to 1,800 parts by weight and more preferably 700 to 1,500 parts by weight.

### Additive (E)

The aforementioned positive photosensitive resin composition optionally includes an additive (E) that includes but is not limited to an adhesiveness improver, a surface-leveling agent, a diluent, a sensitizer and the like.

Examples of the adhesiveness improver include but are not limited to a melamine compound and a silane compound, thereby strengthening the adhesiveness of the positive photosensitive resin composition attached on the substrate. Specific examples of the melamine compound include but are not limited to the products available commercially as Cymel-300 and Cymel-303 (CYTEC Industries Inc., NJ, U.S.A); and MW-30 MH, MW-30, MS-11, MS-001, MX-750 and MX-706 (Sanwa Chemical Co., Ltd, Japan). Specific examples of the silane compound, include but are not limited to vinyltrimethoxysilane, vinyltriethoxysilane, 3-(methyl)acryloxypropyl trimethoxysilane, vinyl tris(2-methoxyethoxy) silane, N-(2-aminoethyl)-3-aminopropyl methyl dimethoxysilane, N-(2-aminoethyl)-3-aminopropyl trimethoxysilane, 3-aminopropyl triethoxysilane, 3-glycidoxypropyltrimetoxysilane, 3-glycidoxypropylmethyldimetoxysilane, 2-(3,4-epoxycyclohexyl) ethyltrimethoxysilane, 3-chloropropylmethyldimetoxysilane, 3-chloropropyltrimetoxysilane, 3-methacryloxy propyl trimethoxysilane, 3-mercapto propyltrimethoxysilane, bis(1,2-trimethoxysilyl)ethane. Based on 100 parts by weight of the novolac resin (A), an amount of the melamine compound is typically 0 to 20 parts by weight, preferably 0.5 to 18 parts by weight and more preferably 1.0 to 15 parts by weight; and an amount of the silane compound is typically 0 to 2 parts by weight, preferably 0.001 to 1 parts by weight and more preferably 0.005 to 0.8 parts by weight.

Examples of the aforementioned surface-leveling agent include but are not limited to a fluorosurfactant and a silicon-based surfactant. Specific examples of the fluorosurfactant include but are not limited to the products available commercially as trade names of Fluorad FC-430 and FC-431 (manufactured by 3M Specialty Materials Division, MN, U.S.A); and trade names of F top EF122A, 122B, 122C, 126 and BL20 (manufactured by Tochem product Co., Ltd). Specific examples of the silicon-based surfactant include but are not limited to the products available commercially as trade names of SF8427 and SH29PA (Dow Corning Toray Silicone Co., Ltd). Based on 100 parts by weight of the novolac resin (A), an amount of the aforementioned surfactant is typically 0 to 1.2 parts by weight, preferably 0.025 to 1.0 parts by weight and more preferably 0.050 to 0.8 parts by weight.

Specific examples of the diluent include but are not limited to the products available commercially as trade names of RE801 and RE802 (manufactured by Teikoku Printing Inks Mfg. Co., Ltd. JP).

Specific examples of the sensitizer include but are not limited to the products available commercially as trade names of TPPA-1000P, TPPA-100-2C, TPPA-1100-3C, TPPA-1100-4C, TPPA-1200-24X, TPPA-1200-26X, TPPA-1300-235T, TPPA-1600-3M6C and TPPA-MF (manufactured by Honsyu Chemical Industry Ltd., JP). Among those sensitizers, TPPA-1600-3M6C and TPPA-MF are preferred. The aforementioned sensitizers may be used alone or in combinations of two or more. Based on 100 parts by weight of the novolac resin (A), an amount of the aforementioned additive (E) is typically 0 to 20 parts by weight, preferably 0.5 to 18 parts by weight and more preferably 1.0 to 15 parts by weight.

In addition, the positive photosensitive resin composition can be added with other additives such as plasticizer, stabilizer and so on if needed.

### Preparation of Positive Photosensitive Resin Composition

The positive photosensitive resin composition of the present invention can be prepared by mixing the novolac resin (A), the ortho-naphthoquinone diazide sulfonic acid ester (B), the dye (C) and the solvent (D) well in a mixer until all components are formed into a solution state. The positive photosensitive resin composition is optionally added with the additive (E) such as the adhesiveness improver, the surface-leveling agent, the diluent, the sensitizer and so on if needed.

### Method for Forming Patterns by Using Positive Photosensitive Resin Composition

The positive photosensitive resin composition of the present invention can be subjected to a prebake step, an exposure step, a development step and a postbake step, so as to forming patterns on a substrate.

Specifically, in the method for forming patterns by using the positive photosensitive resin composition, the resin composition is applied on the substrate by various coating methods, for example, spin coating, cast coating or roll coating methods. And then, the coated resin composition is prebaked to remove the solvent, thereby forming a prebaked coating film. The prebake step is carried out in various conditions, for example, at 70 to 110° C. for 1 to 15 minutes, which depend upon the kinds and the mixing ratio of components.

After the prebake step, the prebaked coating film is exposed under a given mask, and immersed in a developing solution at 23±2° C. for 15 seconds to 5 minutes, thereby removing undesired areas and forming a given pattern. The exposure light is preferably g-line, h-line, l-line and so on, which may be generated by a UV illumination device such as (super) high-pressure mercury lamp or metal halide lamp.

Specific examples of the developing solution include but are not limited to alkaline compounds such as sodium hydroxide, potassium hydroxide, sodium carbonate, sodium hydrogen carbonate, potassium carbonate, potassium hydrogen carbonate, sodium silicate, sodium methyl silicate, ammonia solution, ethylamine, diethylamine, dimethylethylanolamine, tetramethylammonium hydroxide, tetraethylammonium hydroxide, choline, pyrrole, piperidine, 1,8-diazabicyclo -(5,4,0)-7-undecene and the like.

The concentration of the developing solution is preferably 0.001 weight percent (wt %) to 10 wt %, more preferably 0.005 wt % to 5 wt %, and much more preferably 0.01 wt % to 1 wt %.

When the aforementioned alkaline compounds are included in the developing solution, the coating film can be washed by water after being developed, and then be dried by compressed air or nitrogen gas. Next, the coating film is postbaked by using a hot plate, an oven or other heating device. The postbake step can be carried out at 100 to 250° C. for 1 to 60 minutes on the hot plate for 5 to 90 minutes 1n the oven. After those steps, the pattern is formed on the substrate.

### Thin Film Transistor (TFT) Array Substrate

The method for making a thin film transistor (TFT) array substrate is based on the aforementioned method for forming the patterns. Similarly, the positive photosensitive resin composition is applied on a substrate by various coating methods, for example, spin coating, cast coating or roll coating methods, for forming a positive photoresist layer, in which the aforementioned substrate is a glass or plastic substrate with a film of aluminum, chromium, silicon nitride or amorphous silicon formed thereon. Next, through the prebake, exposure, development and post bake steps for forming the photosensitive resin pattern, the pattern is etched and then the photoresist is stripped. Those steps are repeated for obtaining the TFT array substrate with one or more TFTs or electrodes disposed thereon.

Reference will now be made in detail to the present embodiments of the invention, examples of which are illustrated in the accompanying drawings. Wherever possible, the same reference numbers are used in the drawings and the description to refer to the same or like parts.

Reference is made to FIG. 1, which depicts a partial cross-sectional diagram of a TFT array substrate for a LCD device according to an embodiment of the present invention. First of all, a gate 102a and a storage capacitance Cs electrode 102b are disposed on an aluminum film of a glass substrate 101. Next, a silicon oxide (SiOx) film 103 or a silicon nitride (SiNx) film 104 each of which functions as an insulation film is covered over the gate 102a. And then, an amorphous silicon (a-Si) film 105 that functions as a semiconductor active layer is formed on the insulation film. Next, another a-Si film 106 doped with nitrogen impurity is disposed on the a-Si film 105 for reducing the interface resistance. Later, a drain 107a and a source 107b are formed by using a metal such as aluminum or the like, in which the drain 107a is connected to a data signal line (unshown), and the source 107b is connected to the pixel electrode (or sub-pixel electrode) 109. Subsequently, another silicon nitride film is disposed which functions as a protection film 108 for protecting the a-Si film 105 (as the semiconductor active layer), the drain 107a or the source 107b.

### LCD Device

The LCD device of the present invention comprises the aforementioned TFT array substrate with the patterns formed by the present method. In addition, the LCD device also includes other components if needed.

Specific examples of the LCD device basically include but are not limited to the following. (1) The aforementioned TFT array substrate (driver substrate) and a color filter (CF) substrate are disposed oppositely, spacers are disposed therebetween for forming a space, and LC material is sealed in the space, so as to assemble the LCD device. In such case, the TFT array substrate has driving components (including TFTs) and pixel electrodes (electrically conductive layer) arranged thereon, and the CF substrate is constituted by CF and a counter electrode (electrically conductive layer). Alternatively, (2) the aforementioned TFT array substrate is combined with the CF substrate for forming a one-piece CF-TFT array substrate, and the one-piece CF-TFT array substrate and a counter substrate with the counter electrode (electrically conductive layer) are disposed oppositely, spacers are disposed therebetween for forming a space, and the LC material is sealed in the space, so as to assemble the LCD device. The LC material can be any prior LC compound or composition without any limitation.

Specific examples of the aforementioned electrically conductive layer include but are not limited to indium tin oxide (ITO) film; a metal film such as aluminum, zinc, copper, iron, nickel, chromium, molybdenum or the like; and metal oxide film such as silicon dioxide or the like. Among those films, a transparent film is preferred, and the ITO film more preferred.

Specific examples of the aforementioned substrate used in the TFT array substrate, the CF substrate and the counter substrate include but are not limited to the prior glass such as Na—Ca glass, low-swelling glass, alkali-free glass, a quartz glass or the like. In addition, the aforementioned substrate may include a plastic substrate.

Thereinafter, various applications of the present invention will be described in more details referring to several exemplary embodiments below, while not intended to be limiting. Thus, one skilled in the art can easily ascertain the essential characteristics of the present invention and, without departing from the spirit and scope thereof, can make various changes and modifications of the invention to adapt it to various usages and conditions.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a partial cross-sectional diagram of a TFT array substrate for a LCD device according to the present invention.

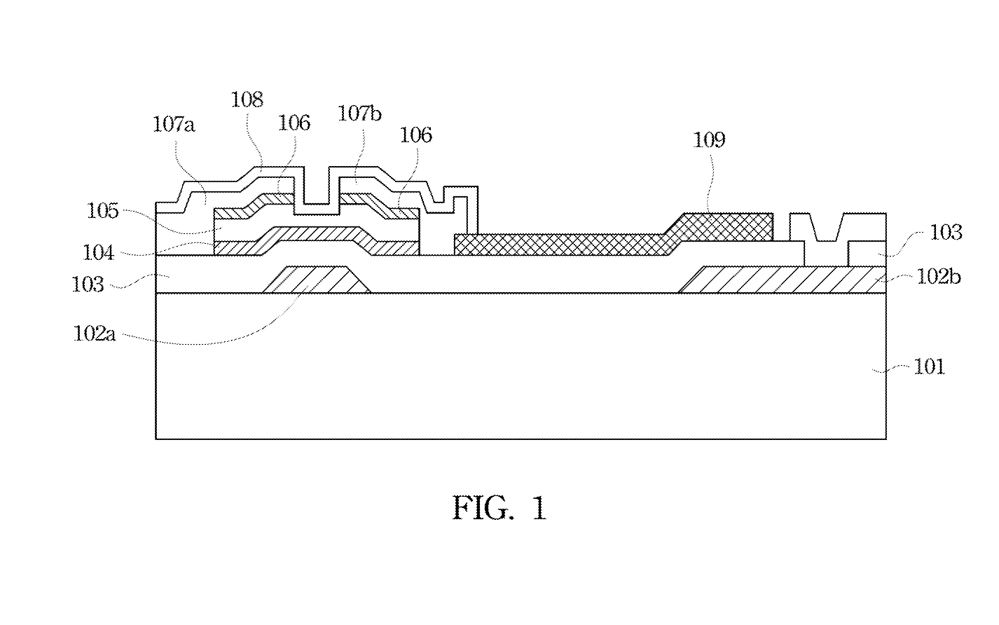

### DETAILED DESCRIPTION

Thereinafter, various applications of the present invention will be described in more details referring to several exemplary embodiments below, while not intended to be limiting. Thus, one skilled in the art can easily ascertain the essential characteristics of the present invention and, without departing from the spirit and scope thereof, can make various changes and modifications of the invention to adapt it to various usages and conditions.

### EXAMPLES

### Synthesis Example 1

### Method of Synthesizing High-Ortho Novolac Resin (A-1-1)

A 1000 mL four-necked conical flask equipped with a nitrogen inlet, a stirrer, a heater, a condenser and a thermometer was purged with nitrogen, and the components shown in Table 1 were charged to the flask. The aforementioned components comprising 64.89 g (0.6 mole) of m-cresol, 43.26 g (0.4 mole) of p-cresol, 0.5 g (0.0028 mole) of manganese acetate and 48.70 g (0.6 mole) of 37 wt % formaldehyde solution were stirred slowly to polymerize for 3 hours. Next, 1.38 g (0.01 mole) of salicylic acid was added and the pH was adjusted to pH 3.5, followed by dehydration under a decreased pressure at 300 mmHg for 30 minutes. After the reaction was completed, the reaction solution was slowly heated to 150° C. for evaporating the solvent, thereby obtaining a high-ortho novolac resin (A-1-1).

The methylene binding number of the resulted high-ortho novolac resin (A-1-1) was determined by carbon-13 nuclear magnetic resonance (¹³C-NMR) spectrometry, and the ratio of ortho-ortho methylene bonding to all methylene bonding was calculated by the following method and resulted in TABLE 1.

### Synthesis Example 2

### Method of Synthesizing High-Ortho Novolac Resin (A-1-2)

A 1000 mL four-necked conical flask equipped with a nitrogen inlet, a stirrer, a heater, a condenser and a thermometer was purged with nitrogen, and the components shown in Table 1 were charged to the flask. The aforementioned components comprising 5.40 g (0.05 mole) of o-cresol, 64.89 g (0.6 mole) of m-cresol, 37.86 g (0.35 mole) of p-cresol, 0.5 g (0.0028 mole) of manganese acetate and 52.75 g (0.65 mole) of 37 wt % formaldehyde solution were stirred slowly to polymerize for 3 hours. Next, 1.10 g (0.008 mole) of salicylic acid was added and the pH was adjusted to pH 4.0, followed by dehydration under reduced pressure at 300 mmHg for 30 minutes. After the reaction was completed, the reaction solution was slowly heated to 150° C. for evaporating the solvent, thereby obtaining a high-ortho novolac resin (A-1-2).

The methylene binding number of the resulted high-ortho novolac resin (A-1-2) was determined by ¹³C-NMR spectrometry, and the ratio of ortho-ortho methylene bonding to all methylene bonding was calculated by the following method and resulted in TABLE 1.

### Synthesis Example 3

### Method of Synthesizing High-Ortho Novolac Resin (A-1-3)

A 1000 mL four-necked conical flask equipped with a nitrogen inlet, a stirrer, a heater, a condenser and a thermometer was purged with nitrogen, and the components shown in Table 1 were charged to the flask. The aforementioned components comprising 64.89 g (0.6 mole) of m-cresol, 43.26 g (0.4 mole) of p-cresol, 0.5 g (0.0028 mole) of manganese acetate and 56.82 g (0.7 mole) of 37 wt % formaldehyde solution were stirred slowly to polymerize for 3 hours. Next, 0.37 g (0.003 mole) of benzoic acid was added and the pH was adjusted to pH 4.8, followed by dehydration under reduced pressure at 300 mmHg for 30 minutes. After the reaction was completed, the reaction solution was added with 0.03 g (0.0002 mole) of dimethyl sulfate and slowly heated to 150° C. for evaporating the solvent, thereby obtaining a high-ortho novolac resin (A-1-3).

The methylene binding number of the resulted high-ortho novolac resin (A-1-3) was determined by ¹³C-NMR spectrometry, and the ratio of ortho-ortho methylene bonding to all methylene bonding was calculated by the following method and resulted in TABLE 1.

### Synthesis Example 4

### Method of Synthesizing Novolac Resin (A-2-1)

A 1000 mL four-necked conical flask equipped with a nitrogen inlet, a stirrer, a heater, a condenser and a thermometer was purged with nitrogen, and the components shown in Table 1 were charged to the flask. The aforementioned components comprising 64.89 g (0.6 mole) of m-cresol, 43.26 g (0.4 mole) of p-cresol, 1.80 g (0.02 mole) of oxalic acid and 48.70 g (0.6 mole) of 37 wt % formaldehyde solution were stirred slowly to polymerize for 3 hours. After the reaction was completed, the reaction solution was heated to 150° C. for evaporating the solvent, thereby obtaining a novolac resin (A-2-1).

The methylene binding number of the resulted novolac resin (A-2-1) was determined by ¹³C-NMR spectrometry, and the ratio of ortho-ortho methylene bonding to all methylene bonding was calculated by the following method and resulted in TABLE 1.

### Synthesis Example 5

### Method of Synthesizing Novolac Resin (A-2-2)

A 1000 mL four-necked conical flask equipped with a nitrogen inlet, a stirrer, a heater, a condenser and a thermometer was purged with nitrogen, and the components shown in Table 1 were charged to the flask. The aforementioned components comprising 64.89 g (0.6 mole) of m-cresol, 32.45 g (0.3 mole) of p-cresol, 12.22 g (0.1 mole) of 2,5-dimethylphenol, 0.09 g (0.01 mole) of oxalic acid and 44.64 g (0.55 mole) of 37 wt % formaldehyde solution were stirred slowly to polymerize for 3 hours. After the reaction was completed, the reaction solution was heated to 150° C. for evaporating the solvent, thereby obtaining a novolac resin (A-2-2).

The methylene binding number of the resulted novolac resin (A-2-2) was determined by ¹³C-NMR spectrometry, and the ratio of ortho-ortho methylene bonding to all methylene bonding was calculated by the following method and resulted in TABLE 1.

TABLE 1

| Synthesis | The ratio of ortho-ortho methylene |
|---|---|
| Examples | bonding to all methylene bonding |
| A-1-1 | 18% |
| A-1-2 | 20% |
| A-1-3 | 25% |
| A-2-1 | 16% |
| A-2-2 | 14% |

### Method of Manufacturing Positive Photosensitive Resin Composition

The following examples are directed to the preparation of the positive photosensitive resin composition of Examples 1 to 9 and Comparative Examples 1 to 4 according to TABLE 2.

### Example 1

100 parts by weight of the high-ortho novolac resin (A-1-1), 20 parts by weight of the ester of 2,3,4-trihydroxybenzophenone and 1,2-naphthoquinone diazide-5-sulfonic acid (B-1) and 5 parts by weight of the ester of 2,3,4,4′-tetrahydroxybenzophenone and 1,2-naphthoquinone diazide-5-sulfonic acid (B-2), 3 parts by weight of C.I. Solvent Red 91 (trade name of Savinyl Red 3BLS; made by Clariant Co.) (C-1) were added into 800 parts by weight of propylene glycol monomethyl ether acetate (PGMEA; D-1), all of which were stirred and mixed well in a shaking mixer, so as to form a positive photosensitive resin composition of Example 1. And then, the temporal stability of the positive photosensitive resin composition, the resolution and the residual film ratio of the pattern formed by the positive photosensitive resin composition were determined by using the following evaluation methods and resulted in TABLE 2.

### Examples 2 to 9

Examples 2 to 9 were practiced with the same method as in Example 1 by using various kinds or usage of the novolac resin (A), the ortho-naphthoquinone diazide sulfonic acid ester (B), the dye (C) and the solvent (D) listed in TABLE 2.

### Comparative Examples 1 to 4

Comparative Examples 1 to 4 were practiced with the same method as in Example 1 by using various kinds or usage of the novolac resin (A), the ortho-naphthoquinone diazide sulfonic acid ester (B), the dye (C) and the solvent (D) listed in TABLE 2.

Evaluation Method

1. Evaluation of Ratio of Ortho-Ortho Methylene Bonding to All Methylene Bonding

The methylene binding number of the resulted novolac resin (A) was determined by ¹³C-NMR spectrometer (AV400, Bruker). And then, the ratios of ortho-ortho methylene bonding to all methylene bonding of Synthesis Examples 1-5 were calculated according to the following equation (III).

$$\begin{matrix}\begin{matrix}Ratio ( \% ) of Ortho \text{-} Ortho \\ Methylene Bonding to\end{matrix} \\ All Methylene Bonding\end{matrix} = \frac{( ortho \text{-} ortho bonding )}{\begin{matrix}\begin{matrix}( ortho \text{-} ortho bonding ) + \\ ( ortho \text{-} para bonding ) +\end{matrix} \\ ( para \text{-} para bonding )\end{matrix}} \qquad ( III )$$

In the equation (III), the ortho-ortho bonding is referred to the number of methylene bonding at the ortho-ortho position, the ortho-para bonding is referred to the number of methylene bonding at the ortho-para position, and the para-para bonding is referred to the number of methylene bonding at the para-para position. Results of ortho-ortho methylene bonding to all methylene bonding calculation were listed in TABLE 1.

2. Temporal Stability

The positive photosensitive resin composition of EXAMPLES 1 to 9 and COMPARATIVE EXAMPLES 1 to 4 were heated in an oven at 45° C. for one month, and the viscosities of the resin compositions before and after the heating treatment were measured to calculate the viscosity changing ratio, thereby evaluating the temporal stability according to the following conditions.

◯: viscosity changing ratio <5%

X: viscosity changing ratio ≧5%

3. Resolution

The positive photosensitive resin composition of EXAMPLES 1 to 9 and COMPARATIVE EXAMPLES 1 to 4 were coated onto a glass substrate by using the spin coating method and then prebaked at 100° C. for 2 minutes, so as to obtain a prebaked coating film with the thickness of 1 μm approximately. The prebaked coating film was exposed by 50 mJ/cm² of UV (generated by AG500-4N Exposure Unit; M&R Nano Technology Co., Ltd) under a line-and-space mask (Falcon Co., Japan), and immersed in 0.84% of potassium hydroxide solution at 23° C. for 1 minute, thereby removing exposed areas, washing by using pure water and forming a given pattern. The resolution is defined by the minimal line width of the pattern and evaluated according to the following conditions.

◯: line width <2 μm

Δ: 2 μm≦line width <3 μm

X: line width ≧3 μm

4. Residual Film Ratio

A thickness (δ_{d1}) of a selected point of the prebaked coating film formed in the “3. Resolution” evaluation was measured. After the prebaked coating film was immersed in the developing solution (0.84% of potassium hydroxide solution) for 1 minute, another thickness (δ_{d2}) of the same selected point was also measured. Later, the residual film ratio was calculated according to the following equation (IV).

Residual Film Ratio(%)=[(δ_{d2})/(δ_{d1})]×100 (IV)

◯: Residual Film ratio ≧90%.

Δ: 90%>Residual Film ratio >80%

X: Residual Film ratio ≦80%

The evaluation results with respect to the temporal stability, the resolution and the residual film ratio of the positive photosensitive resin compositions of Examples and Comparative Examples were listed in TABLE 2.

According to the results of the TABLE 2, the positive photosensitive resin composition will have excellent temporal stability and form better resolution of the pattern if such resin composition includes the high-ortho novolac resin (A-1) with ortho-ortho methylene bonding to all methylene bonding in a ratio of 18% to 25% and the dye (C).

Furthermore, it is necessarily supplemented that, specific compounds, specific compositions, specific reaction conditions, specific processes, specific analyzing methods or specific instruments are employed as exemplary embodiments in the present invention, for illustrating the positive photosensitive resin composition, the method for forming patterns by using the same, the TFT array substrate with the patterns and LCD device having thereof in the present invention. However, as is understood by a person skilled in the art, the positive photosensitive resin composition and the method for forming patterns by using the same in the present invention can include other compounds, other compositions, other reaction conditions, other processes, other analyzing methods or other instruments rather than limiting to the aforementioned examples.

As is understood by a person skilled in the art, the foregoing preferred embodiments of the present invention are illustrated of the present invention rather than limiting of the present invention. In view of the foregoing, it is intended to cover various modifications and similar arrangements included within the spirit and scope of the appended claims. Therefore, the scope of which should be accorded the broadest interpretation so as to encompass all such modifications and similar structure.

TABLE 2

| | | Examples | | | | | | | | |
|---|---|---|---|---|---|---|---|---|---|---|
| Components | | 1 | 2 | 3 | 4 | 5 | 6 | 7 | 8 | 9 |
| Novolac resin (A) | A-1-1 | 100 | | | 100 | | 90 | 80 | | |
| (parts by weight) | A-1-2 | | 100 | | | 100 | | | 70 | |
| | A-1-3 | | | 100 | | | 10 | | | 50 |
| | A-2-1 | | | | | | | 20 | | 50 |
| | A-2-2 | | | | | | | | 30 | |
| Ortho-naphthoquinone diazide | B-1 | 20 | 20 | 15 | 25 | 20 | 20 | 35 | 20 | 20 |
| sulfonic acid ester (B) | B-2 | 5 | 3 | 10 | | | 10 | 5 | 5 | 5 |
| (parts by weight) | | | | | | | | | | |
| Dye (C) | C-1 | 3 | 2 | 1.5 | 1 | | 1 | 5 | | |
| (parts by weight) | C-2 | | | | 1 | 2 | | | 0.1 | 2 |
| | C-3 | | | | | | 0.5 | | | 1 |
| Solvent (D) | D-1 | 800 | 800 | 500 | | 600 | 800 | 1200 | 300 | |
| (parts by weight) | D-2 | | | 350 | 400 | | | | 300 | |
| | D-3 | | | | 400 | | | | | 750 |
| Additive (E) | E-1 | | | | | 0.3 | | | 0.2 | |
| (parts by weight) | E-2 | | | 0.01 | | | | | 0.01 | |
| | E-3 | | | | | | | 0.05 | | |
| Evaluation Results | Temporal Stability | ◯ | ◯ | ◯ | ◯ | ◯ | ◯ | ◯ | ◯ | ◯ |
| | Resolution | ◯ | ◯ | ◯ | ◯ | ◯ | ◯ | ◯ | ◯ | ◯ |
| | Residual Film Ratio | ◯ | ◯ | ◯ | ◯ | ◯ | ◯ | ◯ | ◯ | ◯ |

| | | Comparative | | | |
|---|---|---|---|---|---|
| | | Examples | | | |
| Components | | 1 | 2 | 3 | 4 |
| Novolac resin (A) | A-1-1 | | | 100 | |
| (parts by weight) | A-1-2 | | | | |
| | A-1-3 | | | | |
| | A-2-1 | 100 | | | 100 |
| | A-2-2 | | 100 | | |
| Ortho-naphthoquinone diazide | B-1 | 20 | 20 | 20 | 20 |
| sulfonic acid ester (B) | B-2 | 5 | 5 | 5 | 3 |
| (parts by weight) | | | | | |
| Dye (C) | C-1 | 3 | 3 | | |
| (parts by weight) | C-2 | | | | |
| | C-3 | | | | |
| Solvent (D) | D-1 | 800 | 800 | 800 | 800 |
| (parts by weight) | D-2 | | | | |
| | D-3 | | | | |
| Additive (E) | E-1 | | | | |
| (parts by weight) | E-2 | | | | |
| | E-3 | | | | |
| Evaluation Results | Temporal Stability | ◯ | ◯ | X | X |
| | Resolution | X | X | ◯ | X |
| | Residual Film Ratio | Δ | Δ | ◯ | Δ |

Compounds
B-1 the ester of 2,3,4-trihydroxybenzophenone and 1,2-naphthoquinone diazide-5-sulfonic acid
B-2 the ester of 2,3,4,4′-tetrahydroxybenzophenone and 1,2-naphthoquinone diazide-5-sulfonic acid
C-1 C.I. Solvent Red 91 (trade name of Savinyl Red 3BLS; made by Clariant Co.)
C-2 C.I. Basic Violet 3 (trade name of C3886; made by Sigma Co.)
C-3 C.I. Acid Green 25 (trade name of Sanolin Green GL; made by Clariant Co.)
D-1 Propylene glycol monomethyl ether acetate (PGMEA)
D-2 Ethyl lactate (EL)
D-3 Propylene glycol monoethyl ether (PGEE)
E-1 the surface-leveling agent: trade name of SF8427 (Dow Corning Toray Silicone Co., Ltd)
E-2 the adhesiveness improver: the trade name of Cymel-303 (made by CYTEC Industries Inc., NJ, U.S.A)
E-3 the sensitizer: the trade name of TPPA-MF (manufactured by Honsyu Chemical Industry Ltd., JP)

What is claimed is:

1. A positive photosensitive resin composition, comprising:
a novolac resin (A);
an ortho-naphthoquinone diazide sulfonic acid ester (B);
a dye (C); and
a solvent (D),
wherein the novolac resin (A) includes a high-ortho novolac resin (A-1) that has ortho-ortho methylene bonding to all methylene bonding in a ratio of 18% to 25%.

2. The positive photosensitive resin composition of claim 1, wherein an amount of the high-ortho novolac resin (A-1) is 30 to 100 parts by weight based on 100 parts by weight of the novolac resin (A).

3. The positive photosensitive resin composition of claim 1, wherein an amount of the high-ortho novolac resin (A-1) is 40 to 100 parts by weight based on 100 parts by weight of the novolac resin (A).

4. The positive photosensitive resin composition of claim 1, wherein an amount of the high-ortho novolac resin (A-1) is 50 to 100 parts by weight based on 100 parts by weight of the novolac resin (A).

5. The positive photosensitive resin composition of claim 1, wherein an amount of the dye (C) is 0.1 to 5 parts by weight based on 100 parts by weight of the novolac resin (A).

6. The positive photosensitive resin composition of claim 1, wherein the dye (C) is selected from the group consisting of an acid dye, a basic dye, a direct dye, a sulphur dye, a vat dye, a naphthol dye, a reactive dye, a disperse dye and an oil-soluble dye.

7. A method for forming patterns by subjecting a positive photosensitive resin composition according to claim 1 into a pre-bake step, an exposure step, a developing step and a post-bake step, thereby forming the patterns on a substrate, wherein the positive photosensitive resin composition comprising a novolac resin (A), an ortho-naphthoquinone diazide sulfonic acid ester (B), a dye (C), and a solvent (D), and the novolac resin (A) includes a high-ortho novolac resin (A-1) that has ortho-ortho methylene bonding to all methylene bonding in a ratio of 18% to 25%.

8. The method of claim 7, wherein an amount of the high-ortho novolac resin (A-1) is 30 to 100 parts by weight based on 100 parts by weight of the novolac resin (A).

9. The method of claim 7, wherein an amount of the high-ortho novolac resin (A-1) is 40 to 100 parts by weight based on 100 parts by weight of the novolac resin (A).

10. The method of claim 7, wherein an amount of the high-ortho novolac resin (A-1) is 50 to 100 parts by weight based on 100 parts by weight of the novolac resin (A).

11. The method of claim 7, wherein an amount of the dye (C) is 0.1 to 5 parts by weight based on 100 parts by weight of the novolac resin (A).

12. The method of claim 7, wherein the dye (C) is selected from the group consisting of an acid dye, a basic dye, a direct dye, a sulphur dye, a vat dye, a naphthol dye, a reactive dye, a disperse dye and an oil-soluble dye.

13. A thin-film transistor array substrate comprising a pattern formed by using the method of claim 7 by subjecting a positive photosensitive resin composition into a pre-bake step, an exposure step, a developing step and a post-bake step, thereby forming the pattern on a substrate, wherein the positive photosensitive resin composition comprising a novolac resin (A), an ortho-naphthoquinone diazide sulfonic acid ester (B), a dye (C), and a solvent (D), and the novolac resin (A) includes a high-ortho novolac resin (A-1) that has ortho-ortho methylene bonding to all methylene bonding in a ratio of 18% to 25%.

14. The thin-film transistor array substrate of claim 13, wherein an amount of the high-ortho novolac resin (A-1) is 30 to 100 parts by weight based on 100 parts by weight of the novolac resin (A).

15. The thin-film transistor array substrate of claim 13, wherein an amount of the high-ortho novolac resin (A-1) is 40 to 100 parts by weight based on 100 parts by weight of the novolac resin (A).

16. The thin-film transistor array substrate of claim 13, wherein an amount of the high-ortho novolac resin (A-1) is 50 to 100 parts by weight based on 100 parts by weight of the novolac resin (A).

17. The thin-film transistor array substrate of claim 13, wherein an amount of the dye (C) is 0.1 to 5 parts by weight based on 100 parts by weight of the novolac resin (A).

18. The thin-film transistor array substrate of claim 13, wherein the dye (C) is selected from the group consisting of an acid dye, a basic dye, a direct dye, a sulphur dye, a vat dye, a naphthol dye, a reactive dye, a disperse dye and an oil-soluble dye.

19. A liquid crystal display device comprising a thin-film transistor array substrate of claim 13 having a pattern formed by subjecting a positive photosensitive resin composition into a pre-bake step, an exposure step, a developing step and a post-bake step, thereby forming the pattern on a substrate, wherein the positive photosensitive resin composition comprising a novolac resin (A), an ortho-naphthoquinone diazide sulfonic acid ester (B), a dye (C), and a solvent (D), and the novolac resin (A) includes a high-ortho novolac resin (A-1) that has ortho-ortho methylene bonding to all methylene bonding in a ratio of 18% to 25%.

20. The liquid crystal display device of claim 19, wherein an amount of the high-ortho novolac resin (A-1) is 30 to 100 parts by weight based on 100 parts by weight of the novolac resin (A).

21. The liquid crystal display device of claim 19, wherein an amount of the high-ortho novolac resin (A-1) is 40 to 100 parts by weight based on 100 parts by weight of the novolac resin (A).

22. The liquid crystal display device of claim 19, wherein an amount of the high-ortho novolac resin (A-1) is 50 to 100 parts by weight based on 100 parts by weight of the novolac resin (A).

23. The liquid crystal display device of claim 19, wherein an amount of the dye (C) is 0.1 to 5 parts by weight based on 100 parts by weight of the novolac resin (A).

24. The liquid crystal display device of claim 19, wherein the dye (C) is selected from the group consisting of an acid dye, a basic dye, a direct dye, a sulphur dye, a vat dye, a naphthol dye, a reactive dye, a disperse dye and an oil-soluble dye.
